(19) United States
(12) Patent Application Publication
(10) Pub. No.: US 2005/0014075 A1
(43) Pub. Date: Jan. 20, 2005

(54) Phase edge darkening binary masks

(76) Inventors: Ebo H. Croffie, Portland, OR (US); Kunal N. Taravade, Portland, OR (US); Nicholas K. Eib, San Jose, CA (US)

Correspondence Address: LSI LOGIC CORPORATION, 1621 BARBER LANE, MS: D-106, MILPITAS, CA, 95035, US

(21) Appl. No.: 10/623,344

(22) Filed: Jul. 18, 2003

(51) Int. Cl. G03F 9/00; G03C 5/00

(52) U.S. Cl. 430/5; 430/322; 430/323; 430/324

(57) ABSTRACT

A binary mask and method for improving the aerial image and mask error enhancement factor (MEEF) of binary masks. A phase edge darkening binary mask is provided which has quartz etched, preferably at a depth which corresponds to a phase shift of 180 degrees. A method of manufacturing a phase edge darkening binary mask is also provided, where the method consists of changing the phase of the layout background by etching to take advantage of the phase edge darkening as a result of light leakage through chrome.

### BACKGROUND

The present invention generally relates to photolithography, and more specifically relates to binary masks and methods for improving the aerial image and mask error enhancement factor (MEEF) of binary masks.

Microlithography is used to manufacture integrated circuits, magnetic devices, and other microdevices. In microlithography, a final product is manufactured in a multiple step process, where initially a “resist” material is produced with each pattern subsequently defining a product attribute. “Resists” are generally formed of polymer compositions, and are sensitive to light or other forms of radiation. The patterns are formed in the resist by exposing different regions of the resist material to different radiation doses. In bright regions, chemical changes occur in the resist that cause it to dissolve more easily (for positive resist) or less easily (for negative resists) than in dim regions. The bright and dim regions are exposed using an exposure tool which generally transfers corresponding features from a mask or reticle. The masks or reticles are generally plates of quartz coated with an opaque material such as chrome. The chrome is etched away to form the mask. The radiation used may be, for example, ultraviolet light and x-rays, and the regions of the mask that are opaque and transparent form a pattern of bright and dark when illuminated uniformly.

Typically, a projection lens is used to form an image of the mask pattern on the resist film. The patterns formed in the resist are not identical to those on the mask, and the methods of obtaining the pattern desired for the ultimate manufactured device in spite of deficiencies in the process is called “wavefront engineering.” This includes Optical and Process Correction or Optical Proximity Correction (OPC), wherein edge placements are manipulated, and off-axis illuminations. Among the various devices used are phase shift masks (PSMs), which create desired dark regions through interference. Phase shift masks and their use in photolithography are described in detail in several existing documents, including U.S. Pat. Nos. 5,620,816; 5,807,649; 6,251,549; 6,287,732 and 6,479,196, all of which are incorporated herein by reference in their entirety.

FIG. 1 depicts standard mask processing steps. First, as shown in image A in FIG. 1, a blank mask/resist 10 is coated onto a substrate of chrome 12 and quartz 14. Then, as shown in image B in FIG. 1, the pattern is written and developed. Next, as shown in image C in FIG. 1, the chrome 12 is etched. Finally, as shown in image D in FIG. 1, the resist 10 is stripped and cleaned, leaving a substrate of quartz 14 with a chrome pattern 12 thereon.

Although phase shift masks and their use in photolithography provide distinct advantages, enhancements can be made with regard to improving the aerial image and mask error enhancement factor (MEEF) of binary masks. To improve the aerial image and mask error enhancement factor (MEEF) of binary masks, attenuated phase shift masks, alternating phase shift masks, and rin phase shift masks have been used. However, attenuated phase shift masks are expensive and prone to sidelobe printing, alternating phase shift masks are expensive and prone to image placement errors, and rim phase shift masks require too many processing steps to manufacture.

### OBJECTS AND SUMMARY

An object of an embodiment of the present invention is to provide a phase edge binary mask which provides an improved aerial image and mask error enhancement factor (MEEF).

Another object of an embodiment of the present invention is to provide a method of manufacturing a phase edge binary mask, where the method is relatively easy to perform, and does not consist of too many processing steps.

Briefly, and in accordance with at least one of the foregoing objects, an embodiment of the present invention provides a phase edge darkening binary mask which has quartz etched, preferably at a depth which corresponds to a phase shift of 180 degrees. A method of manufacturing a phase edge darkening binary mask is also provided, where the method consists of changing the phase of the layout background by etching to take advantage of the phase edge darkening as a result of light leakage through chrome.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein:

FIG. 1 provides a series of images (not to scale) which illustrate the steps which are performed during standard mask processing;

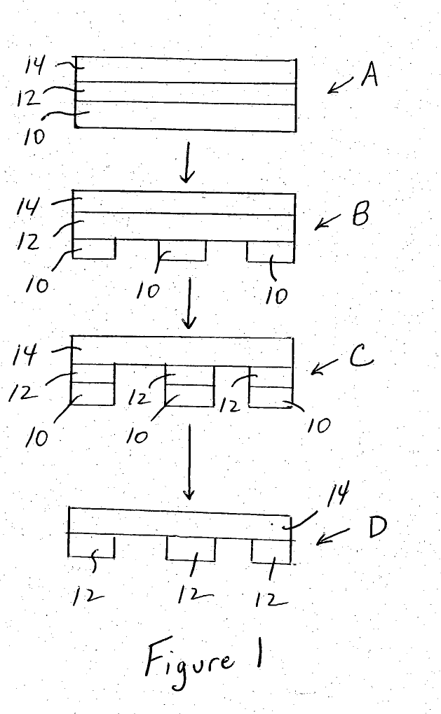

FIG. 2 provides a block diagram of a method of manufacturing a phase edge binary mask, where the method is in accordance with an embodiment of the present invention; and

FIG. 3 provides a series of images (not to scale) which illustrate a phase edge binary mask as it is being manufactured using the method shown in FIG. 2.

### DESCRIPTION

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

An embodiment of the present invention provides a phase edge darkening binary mask which has quartz etched, preferably at a depth which corresponds to a phase shift of 180 degrees. Another embodiment of the present invention provides a method of manufacturing a phase edge darkening binary mask, where the method consists of changing the phase of the layout background by etching to take advantage of the phase edge darkening as a result of light leakage through chrome. As such, the aerial image and mask error enhancement factor (MEEF) is improved.

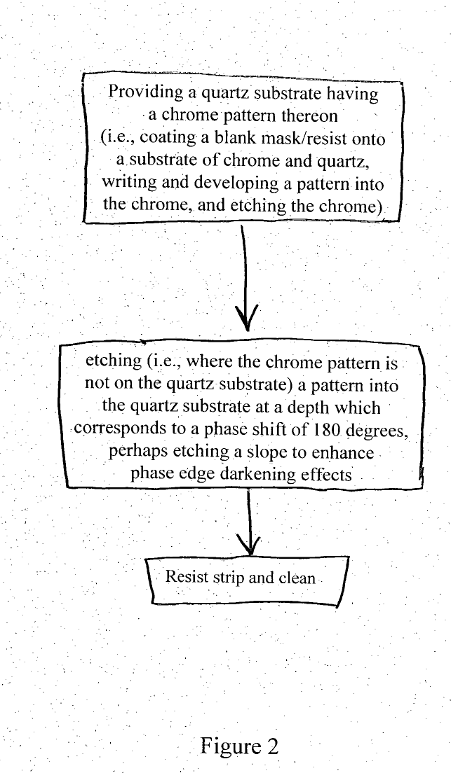

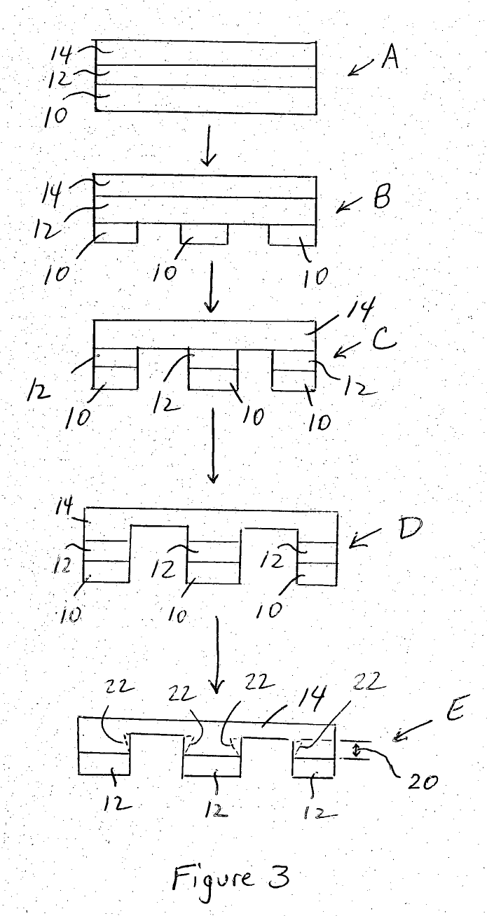

FIG. 2 provides a block diagram of a method of manufacturing a phase edge binary mask, where the method is in accordance with an embodiment of the present invention, and FIG. 3 provides a series of images (not to scale) which illustrate a phase edge binary mask as it is being manufactured using the method shown in FIG. 2.

First, as shown in FIG. 2 and in image A in FIG. 3, a blank mask/resist 10 is coated onto a substrate of chrome 12 and quartz 14. Then, as shown in FIG. 2 and in image B in FIG. 3, the pattern is written and developed. Next, as shown in FIG. 2 and in image C in FIG. 3, the chrome 12 is etched.

Subsequently, as shown in FIG. 2 and in image D in FIG. 3, alter the chrome 12 is etched, the quartz 14 is etched. Preferably, as shown in FIG. 2 and in image E in FIG. 3, the quartz 14 is etched to a depth (dimension 20) that corresponds to a phase shift of 180 degrees. As such, the phase of the layout background is changed by etching to take advantage of the phase edge darkening as a result of light leakage through the chrome 12. Preferably, a pattern is etched into the quartz 14, and the pattern is etched where the chrome 12 is not located on the quartz 14. As shown by the dotted lines 22 in image E in FIG. 3, the etch may be sloped to enhance phase edge darkening effects. As shown in FIG. 2 and in image E in FIG. 3, after the chrome 12 is etched and the quartz 14 is etched, the resist 10 is stripped and cleaned.

By etching into the quartz, preferably at a depth which corresponds to a phase shift of 180 degrees, the phase of the layout background is changed to take advantage of the phase edge darkening as a result of light leakage through chrome. As such, the aerial image and mask error enhancement factor (MEEF) is improved. The mask can be exposed with strong off-axis illumination such as quadropole or dipole to achieve enhanced resolution and MEEF. The technique can be used with any wavelength of exposure system provided the etched depth is adjusted accordingly.

While an embodiment of the present invention is shown and described, it is envisioned that those skilled in the art may devise various modifications of the present invention without departing from the spirit and scope of the appended claims.

1. A binary mask comprising: a quartz substrate; and a chrome pattern on the quartz substrate, wherein the quartz substrate includes at least one etch at a location at which the chrome pattern is not.

2. A binary mask as recited in claim 1, wherein said at least one etch has a depth which corresponds to a phase shift of 180 degrees.

3. A binary mask as recited in claim 1, wherein the quartz substrate includes an etched pattern thereon.

4. A binary mask as recited in claim 3, wherein the etched pattern is located where the chrome pattern is not on the quartz substrate.

5. A binary mask as recited in claim 1, wherein the at least one etch is sloped to enhance phase edge darkening effects.

6. A binary mask as recited in claim 2, wherein the at least one etch is sloped to enhance phase edge darkening effects.

7. A binary mask as recited in claim 3, wherein the etched pattern is sloped to enhance phase edge darkening effects.

8. A binary mask as recited in claim 3, wherein the at least one etch has a depth which is selected such that the mask can be exposed with a given wavelength of exposure system.

9. A method of manufacturing a binary mask, said method comprising: providing a quartz substrate having a chrome pattern thereon; and etching the quartz substrate.

10. A method as recited in claim 9, wherein the step of etching the quartz substrate comprises etching at a depth which corresponds to a phase shift of 180 degrees.

11. A method as recited in claim 9, wherein the step of etching the quartz substrate comprises etching a pattern into the quartz substrate.

12. A method as recited in claim 9, wherein the step of etching the quartz substrate comprises etching where the chrome pattern is not on the quartz substrate.

13. A method as recited in claim 9, wherein the step of providing a quartz substrate having a chrome pattern thereon comprises coating a blank mask/resist onto a substrate of chrome and quartz, writing and developing a pattern into the chrome, and etching the chrome.

14. A method as recited in claim 9, wherein the step of etching the quartz substrate comprises etching a slope to enhance phase edge darkening effects.

15. A method as recited in claim 9, wherein the step of etching the quartz substrate comprises etching a slope to enhance phase edge darkening effects.

16. A method as recited in claim 11, wherein the step of etching the quartz substrate comprises etching a slope to enhance phase edge darkening effects.

17. A method as recited in claim 12, wherein the step of etching the quartz substrate comprises etching a slope to enhance phase edge darkening effects.

18. A method as recited in claim 14, wherein the step of etching the quartz substrate comprises etching a slope to enhance phase edge darkening effects.

19. A method as recited in claim 9, wherein the step of etching comprises etching to a depth which provides that the mask can be effectively exposed with a given wave length of exposure system.
